(19) United States
(12) Patent Application Publication
(10) Pub. No.: US 2005/0156712 A1
(43) Pub. Date: Jul. 21, 2005

(54) Method of transferring information in radio system, radio system and terminal device

(76) Inventor: Kimmo Jyrinki, Oulu (FI)

Correspondence Address: CRAWFORD MAUNU PLLC, 1270 NORTHLAND DRIVE, SUITE 390, ST. PAUL, MN, 55120, US

(21) Appl. No.: 11/014,656

(22) Filed: Dec. 16, 2004

(30) Foreign Application Priority Data
Dec. 22, 2003 (FI) 20031894

(51) Int. Cl. H01L 29/51; H01L 29/74

(52) U.S. Cl. 340/286.01

(57) ABSTRACT

A method of transferring information in a radio system, a radio system and a terminal device. The radio system comprises a terminal device, a remote device communicating with the terminal device on a short-range wireless connection, and a charger. On the basis of a charger connection between the terminal device and the charger being established as well as detecting that the terminal device and the remote device are located at a distance from one another enabling a short-range wireless connection to be established therebetween, the radio system is configured to establish a short-range wireless connection between the terminal device and the remote device and to transfer information between the terminal device and the remote device by using the established short-range wireless connection.

### FIELD

The invention relates to a method of transferring information in a radio system, a radio system and a terminal device.

### BACKGROUND

Increasingly larger amounts of information may be downloaded to and stored in prior art terminal devices, such as mobile equipment or media devices. Furthermore, the terminal devices enable valuable personal contents, such as photographs, drawings, video clips and other documents, to be produced for a user. It is common for a terminal device to contain valuable information that is not available elsewhere. The user may, for example, use the calendar or contact information on his or her mobile equipment as the single or most important source of information. Furthermore, even considerable numbers of photographs, video clips, games, different documents and programs may be produced by the terminal devices or stored therein and downloaded thereto. It is still a fact, however, that due to a sudden failure or possible breakage or loss of a terminal device, the important information stored only in the memory of the particular terminal device may be lost forever. It is also common for one user to have several different terminal devices in his or her use. In such a case, it is necessary to synchronize certain information, such as a calendar and contact information, between the devices.

Information contained in terminal devices may be transferred e.g. into the memory of another terminal device or computer. However, transferring information between e.g. a terminal device and a computer requires several procedures of the user. For example, first the terminal device has to be connected to the computer by means of a cable, then the necessary software has to be opened, the material to be transferred has to be selected, and then the transfer of information has to be initiated. Information may be transferred between a terminal device and a computer also wirelessly, but the user is nevertheless required to go to several different menus in order to implement the transfer of information. Since it is time-consuming and laborious for the user to backup copy information from a terminal device to another device, it is often left undone. Consequently, important information stored only in the memory of the terminal device may be lost forever when the terminal device breaks down or is lost, for example. Similarly, synchronization of information contained in several devices possessed by a single user is often ignored completely, which means that the contents e.g. of certain frequently updated information contained in the devices are not identical in the different devices.

### BRIEF DESCRIPTION

An object of the invention is to provide a method of transferring information in a radio; system, and a radio system and a terminal device implementing the method so as to reduce problems of the prior art. An aspect of the invention is a method of transferring information in a radio system, the method comprising detecting that a charger connection is established between a terminal device and a charger, and detecting that the terminal device and a remote device are located at a distance from one another enabling a short-range wireless connection to be established therebetween. The method of the invention comprises, on the basis of the charger connection between the terminal device and the charger being established as well as detecting that the terminal device and the remote device are located at a distance from one another enabling a short-range wireless connection to be established therebetween, establishing a short-range wireless connection between the terminal device and the remote device and transferring information between the terminal device and the remote device by using the established short-range wireless connection.

The invention further relates to a radio system comprising a terminal device, a remote device communicating with the terminal device on a short-range wireless connection, and a charger, in which radio system the terminal device is configured to detect that a charger connection is established between the terminal device and the charger and to detect that the terminal device and the remote device are located at a distance from one another enabling a short-range wireless connection to be established therebetween. In the radio system of the invention, the radio system, on the basis of the charger connection between the terminal device and the charger being established as well as detecting that the terminal device and the remote device are located at a distance from one another enabling a short-range wireless connection to be established therebetween, is configured to establish a short-range wireless connection between the terminal device and the remote device and to transfer information between the terminal device and the remote device by using the established short-range wireless connection.

A further aspect of the invention is a terminal device in a radio system, the terminal device being configured to detect that a charger connection is established between the terminal device and a charger, and to detect that the terminal device and a remote device are located at a distance from one another enabling a short-range wireless connection to be established therebetween. The terminal device, on the basis of the charger connection being established as well as detecting that the terminal device and the remote device are located at a distance from one another enabling a short-range wireless connection to be established therebetween, is configured to establish a short-range wireless connection between the terminal device and the remote device and to transfer information between the terminal device and the remote device by using the established short-range wireless connection.

The invention further relates to a terminal device in a radio system, the terminal device comprising means for detecting that a charger connection is established between the terminal device and a charger, and means for detecting that the terminal device and a remote device are located at a distance from one another enabling a short-range wireless connection to be established therebetween. The terminal device further comprises means for establishing a short-range wireless connection between the terminal device and the remote device and for transferring information between the terminal device and the remote device by using the established short-range wireless connection on the basis of the charger connection between the terminal device and the charger being established as well as detecting that the terminal device and the remote device are located at a distance from one another enabling a short-range wireless connection to be established therebetween.

The method, radio system and terminal device of the invention provide several advantages. No separate procedures are required of the user in order to transfer information, but information is transferred automatically. Furthermore, information is transferred quite regularly, which reduces the risk of loosing important information should device failures occur.

### LIST OF DRAWINGS

The invention is now described in closer detail in connection with preferred embodiments and with reference to the accompanying drawings, in which

FIG. 1 shows an example of a structure of a radio system,

FIG. 2 shows examples of a terminal device and a remote device of a radio system,

FIG. 3 shows an example of a method of transferring information in a radio system, and

FIG. 4 shows another example of a method of transferring information in a radio system.

### DESCRIPTION OF EMBODIMENTS

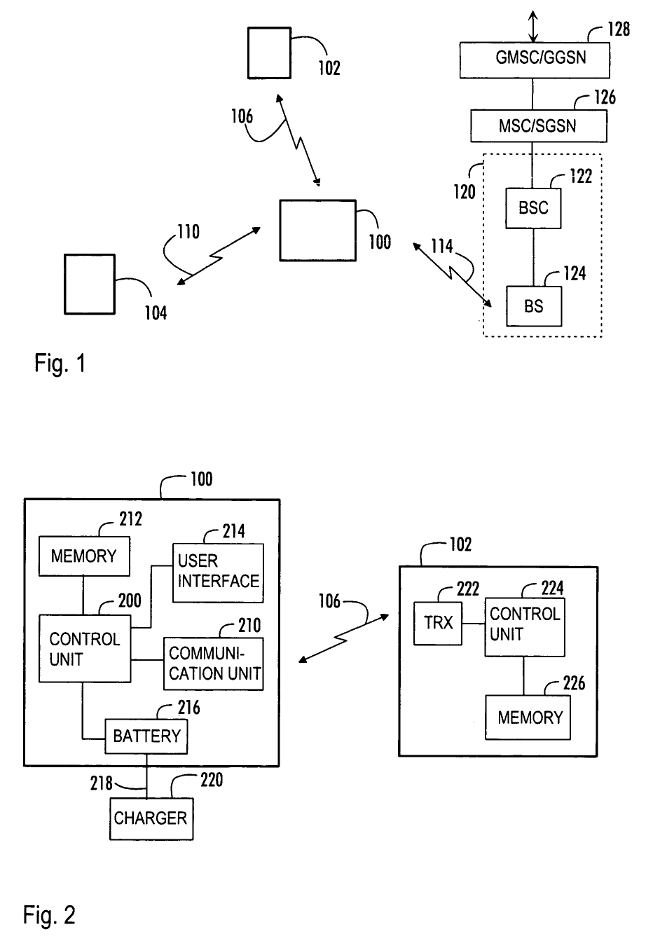

FIG. 1 shows an example of a radio system to which the disclosed solution for transferring information may be applied. The radio system may be based e.g. on GSM (Global System for Mobile Communications), WCDMA (Wideband Code Division Multiple Access) or CDMA (Code Division Multiple Access) technology.

The radio system in FIG. 1 comprises a terminal device 100 and one or more remote devices 102, 104. The terminal device 100 is e.g. mobile equipment, a media device or a PDA (Personal Digital Assistant) device. The remote device 102, 104, in turn, is e.g. other mobile equipment, a peripheral device used in connection with the terminal device 100, an image processing device, a backup copying unit, a computer, a PDA device, a digibox, a PVR/DVR (Personal/Digital Video Recorder) device or any electronic device containing storage capacity/memory.

A mobile telephone network corresponds e.g. to a combined structure of the GSM (Global System for Mobile Communications) and GPRS (General Packet Radio System) systems. GSM network elements are responsible for implementing circuit-switched connections and GPRS network elements are responsible for packet-switched connections. Some of the network elements may, however, be shared by both systems.

A centre 126 represents a mobile services switching centre MSC and a serving GPRS support node SGSN, which enable circuit and packet switched connections in a radio system. The mobile telephone network comprises e.g. a gateway 128, which comprises a gateway mobile service switching centre GMSC and a gateway GPRS support node GGSN. The GMSC is responsible for circuit-switched connections between the mobile telephone network and external networks, such as a public land mobile network PLMN, or a public switched telephone network PSTN while the GGSN is responsible for packet-switched connections between the mobile telephone network and external networks, such as the Internet.

The centre 126 controls a radio access network RAN 120, which comprises e.g. at least one base station controller BSC 122. The base station controller 122 controls at least one base station 124. The base station controller 122 may also be called a radio network controller and the base station 124 may be called Node B. The terminal device 100 of the radio system may communicate with at least one base station 124 via an air interface.

A remote device 102, 104 is e.g. for attending to certain tasks. One of the remote devices 102, 104 may be e.g. specifically for image processing and another remote device 102, 104, in turn, e.g. a video recorder equipped with a hard disk. Information may be stored in the remote devices' own memories. The remote devices 102, 104 may communicate with the terminal device 100 by using e.g. short-range wireless connections 106, 110, such as Bluetooth, infrared, ultra wideband or WLAN (Wireless Local Area Network) connections. The terminal device 100 is also configured to communicate with other systems, such as the Internet, by using e.g. short-range wireless connections or GSM/GPRS/EDGE connections 114. It is possible that the remote device 102, 104 is capable of establishing external connections to other systems.

FIG. 2 shows an example of a terminal device 100 and a remote device 102 according to the disclosed radio system. In the example, the terminal device 100 comprises at least a control unit 200, which controls the functions of the terminal device 100. The terminal device 100 further comprises e.g. one or more of the following elements: a memory 212, a user interface 214, a communication unit 210 and a battery 216. The user interface 214 enables the user of the terminal device 100 to use the device. The communication unit 210 may comprise a transceiver and an antenna, which enable the terminal device 100 to receive and transmit signals. The terminal device may also comprise several communication units 210 such that different communication systems (Bluetooth, WLAN, GSM) may be provided with transceivers and antennas of their own. The terminal device 100 may also include several different other elements, depending on the purpose of use of the terminal device. A charger 220 is an enhancement for the terminal device 100, enabling the battery 216 contained in the terminal device 100 to be charged by establishing a charger connection 218 to the charger 220. The terminal device 100 is configured to communicate with the remote device 102 on a short-range wireless connection 106. The remote device 102 comprises e.g. one or more of the following elements: a transceiver 222 for communicating with the terminal device 100, a control unit 224 controlling the functions of the remote device 102, and a memory 226. It is also feasible that the charger 220 is a part of the remote device 102, in which case the terminal device 100 could communicate with the remote device 102 by also using a wired connection.

The control units 200, 224 of the terminal device 100 and the remote device 102 refer to blocks which control the operation of the devices and which nowadays are usually implemented as a processor including its software, but different hardware implementations are also possible, e.g. a circuit built using separate logic components or one or more application-specific integrated circuits ASICs. A hybrid of these different ways of implementation is also feasible.

In a disclosed embodiment, a terminal device 100 comprises means 200, 216 for detecting that a charger connection 218 is established between the terminal device 100 and a charger 220, and means 200, 210 for detecting that the terminal device 100 and a remote device 102 are located at a distance from one another enabling a short-range wireless connection to be established therebetween. The means 200, 216 for detecting that the charger connection 218 is established comprise e.g. a control unit 200 and a battery 216. The means 200, 216 for detecting that the terminal device 100 and the remote device 102 are located at a distance from one another enabling a short-range wireless connection to be established therebetween, in turn, comprise e.g. a control unit 200 and a communication unit 210. The terminal device 100 further comprises means 200, 210 for establishing a short-range wireless connection 106 between the terminal device 100 and the remote device 102, and means 200, 210, 212 for transferring information between the terminal device 100 and the remote device 102 by using the established short-range wireless connection 106 on the basis of the charger connection 218 being established as well as detecting that the terminal device 100 and the remote device 102 are located at a distance from one another enabling a short-range wireless connection to be established therebetween. The means 200, 210 for establishing a short-range wireless connection comprise e.g. a control unit 200 and a communication unit 210, and the means 200, 210, 212 for transferring information comprise e.g. a control unit 200, a communication unit 210 and a memory 212.

In a radio system according to the disclosed example, the terminal device 100 is configured to detect that a terminal device 100 and a remote device 102 are located at a distance from one another enabling a short-range wireless connection to be established therebetween such that the terminal device 100 transmits an inquiry message to the remote device 102 and the remote device 102, in turn, transmits a reply message to the terminal device 100. The terminal device 100 may transmit inquiry messages to its environment e.g. at regular intervals and/or e.g. always after a charger connection 218 between the terminal device 100 and a charger 220 has been established. It is also feasible that the remote device 102 transmits an inquiry message to the terminal device 100, and the terminal device 100 detects that the terminal device 100 and the remote device 102 are located at a distance from one another enabling a short-range wireless connection to be established therebetween on the basis of the inquiry message transmitted by the remote device 102.

After it has been detected that a charger connection 218 has been established between the terminal device 100 and the charger 220 as well as the terminal device 100 and the remote device 102 are located at a distance from one another enabling a short-range wireless connection to be established therebetween, on the basis thereof, the terminal device 100 is configured to establish a short-range wireless connection 106 between the terminal device 100 and the remote device 102 and to transfer information between the terminal device 100 and the remote device 102 by using the established short-range wireless connection 106.

Thus, for example, contact or calendar information updated in the terminal device 100 is transferred to the memory 226 of the remote device 102. It is also feasible that information is transferred from the remote device 102 to the memory 212 of the terminal device 100. Information is transferred between the terminal device 100 and the remote device 102 e.g. in order to provide backups or to synchronize information between the devices. Information may thus be transferred both ways; from the terminal device 100 to the remote device 102 and from the remote device 102 to the terminal device 100.

Prior to transferring information from the terminal device 100 to the remote device 102, for example a Bluetooth pairing method may be used for pairing the terminal device 100 and the remote device 102. In pairing, the terminal device 100 and the remote device 102 are introduced to each other e.g. by using a PIN (Personal Identification Number) or a corresponding authentication code and/or passwords. After pairing, the terminal device 100 and the remote device 102 recognize each other so that passwords or authentication codes are no longer necessarily needed when establishing a connection between the devices. It is also feasible that the terminal device 100 automatically logs on to a remote device 102 that has been previously introduced to the terminal device each time when establishing a connection.

The information to be transferred comprises e.g. one or more letters, images, videos, music files, multimedia files, programs or combinations thereof. The information to be transferred may be e.g. synchronization information to be transferred in order to synchronize information contained in the terminal device 100 with information contained in the remote device 102. It is possible to determine the quality and contents of the information to be transferred e.g. in the profiles or application programs, e.g. in a synchronization application program, of the terminal device 100.

Since information transfer is also started on the basis of detecting a charger connection 218 and, during charging, the terminal device 100 is located at least at a short-range connection distance from the remote device 102, it can be assumed that there is sufficiently time to transfer the necessary information to the remote device 102 during charging. A terminal device 100 is often charged in the same place at rather regular intervals, so e.g. important information that needs to be backup-copied also becomes transferred to the memory 226 of the remote device 102 quite regularly.

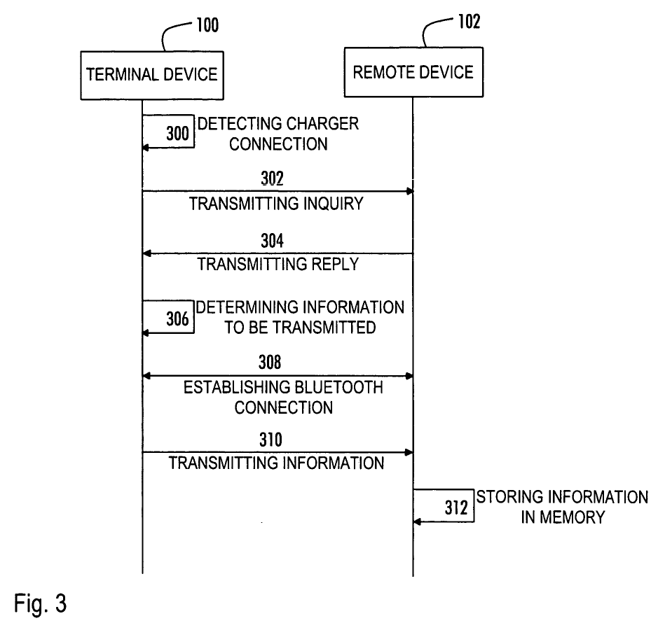

FIG. 3 shows an example of a method of transferring information in a radio system. In FIG. 3, the first vertical line describes communication originating from and terminating at a terminal device 100 and procedures carried out therein. The second vertical line, in turn, describes communication of a remote device 102 and procedures carried out therein.

In an embodiment of the disclosed method, in step 300 it is detected at the terminal device that a charger connection is established. In step 302, the terminal device 100 transmits e.g. an inquiry in order to identify remote devices located at a distance from one another enabling a short-range wireless connection to be established therebetween, the inquiry being detected at a remote device 102. In step 304, the remote device 102, in turn, transmits a reply to the received inquiry to the terminal device 100. It is also feasible that the presence in the vicinity of the terminal device 100 of a previously accepted remote device 102 determined as a backup device is detected in another manner. The remote device 102 may also e.g. transmit an identification signal at regular intervals to be detected at the terminal device 100. On the basis of detecting that a charger connection is established as well as detecting the reply of the remote device 102, the process next moves to step 306, wherein the contents of the information to be transferred are determined at the terminal device, and further to step 308, wherein a short-range wireless connection, e.g. a Bluetooth connection, is established between the terminal device 100 and the remote device 102. In step 310, information is transferred from the terminal device 100 to the remote device 102. Finally, in step 312, the information received from the terminal device 100 is stored in the memory of the remote device 102. After the transfer of the information has been completed, the short-range connection between the terminal device 100 and the remote device 102 may be disconnected.

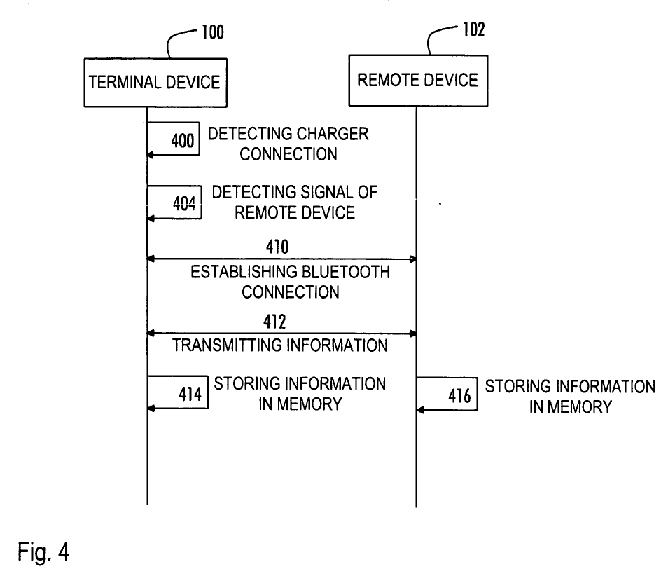

FIG. 4 shows another example of a method of transferring information in a radio system. In FIG. 4, the first vertical line describes communication originating from and terminating at a terminal device 100 and procedures carried out therein. The second vertical line, in turn, describes communication of a remote device 102 and procedures carried out therein.

In step 400, it is detected at the terminal device 100 that a charger connection is established. In step 404, a signal of the remote device 102 is detected at the terminal device 100. On the basis of the charger connection being established and detecting the signal of the remote device, in 410, a Bluetooth connection is established between the terminal device 100 and the remote device 102, and in 412, information is transferred between the terminal device 100 and the remote device 102. Prior to transferring information in 412, the contents of the information to be transferred are determined. In the example of FIG. 4, information is transferred both ways. Information is transmitted from the terminal device 100 to the remote device 102 and information is also received at the terminal device from the remote device 102. The information to be transferred is e.g. synchronization information used for synchronizing the information contained in the terminal device 100 and the remote device 102. Finally, in steps 414 and 416, the transferred information is stored in the memories of the terminal 100 and the remote device 102.

Although the invention has been described above with reference to the example according to the accompanying drawings, it is obvious that the invention is not restricted thereto but can be varied in many ways within the scope of the attached claims.

1. A method of transferring information in a radio system, the method comprising:
detecting that a charger connection is established between a terminal device and a charger, and
detecting that the terminal device and a remote device are located at a distance from one another enabling a short-range wireless connection to be established therebetween,
wherein on the basis of the charger connection between the terminal device and the charger being established as well as detecting that the terminal device and the remote device are located at a distance from one another enabling a short-range wireless connection to be established therebetween, the method further comprising:
establishing a short-range wireless connection between the terminal device and the remote device; and
transferring information between the terminal device and the remote device by using the established short-range wireless connection.

2. A method as claimed in claim 1, the method comprising transferring information from the terminal device to the remote device.

3. A method as claimed in claim 1, the method comprising transferring information from the remote device to the terminal device.

4. A method as claimed in claim 1, the method comprising determining the contents of the information to be transferred in the profiles or application program of the terminal device.

5. A method as claimed in claim 1, wherein the information to be transferred comprises one or more letters, images, videos, music files, multimedia files, programs or combinations thereof.

6. A method as claimed in claim 1, wherein the information to be transferred comprises synchronization information, and information is transferred in order to synchronize information contained in the terminal device with information contained in the remote device.

7. A method as claimed in claim 1, the method further comprising pairing the terminal device and the remote device by using a Bluetooth pairing method prior to transferring information from the terminal device to the remote device.

8. A method as claimed in claim 1, wherein the established short-range wireless connection is an infrared, Bluetooth, ultra wideband or WLAN (Wireless Local Area Network) connection.

9. A radio system comprising a terminal device, a remote device communicating with the terminal device on a short-range wireless connection, and a charger, in which radio system the terminal device is configured to detect that a charger connection is established between the charger and the terminal device and to detect that the terminal device and the remote device are located at a distance from one another enabling a short-range wireless connection to be established therebetween, wherein on the basis of the charger connection between the terminal device and the charger being established as well as detecting that the terminal device and the remote device are located at a distance from one another enabling a short-range wireless connection to be established therebetween, the radio system is configured to: establish a short-range wireless connection between the terminal device and the remote device; and to transfer information between the terminal device and the remote device by using the established short-range wireless connection.

10. A radio system as claimed in claim 9, wherein the radio system is configured to transfer information from the terminal device to the remote device.

11. A radio system as claimed in claim 9, wherein the radio system is configured to transfer information from the remote device to the terminal device.

12. A radio system as claimed in claim 9, wherein the information to be transferred comprises one or more letters, images, videos, music files, multimedia files, programs or combinations thereof.

13. A radio system as claimed in claim 9, wherein the remote device is an image processing device, a media device, a computer, a PDA (Personal Digital Assistant) device, a backup copying unit, a digibox, a PVR/DVR (Personal/Digital Video Recorder) device or mobile equipment.

14. A terminal device in a radio system, the terminal device being configured to detect that a charger connection is established between the terminal device and a charger as well as to detect that the terminal device and a remote device are located at a distance from one another enabling a short-range wireless connection to be established therebetween, wherein on the basis of the charger connection being established as well as detecting that the terminal device and the remote device are located at a distance from one another enabling a short-range wireless connection to be established therebetween, the terminal device is configured to: establish a short-range wireless connection between the terminal device and the remote device; and to transfer information between the terminal device and the remote device by using the established short-range wireless connection.

15. A terminal device as claimed in claim 14, wherein the terminal device is configured to transfer information between the terminal device and the remote device by transmitting information to the remote device.

16. A terminal device as claimed in claim 14, wherein the terminal device is configured to transfer information between the terminal device and the remote device by receiving information from the remote device.

17. A terminal device as claimed in claim 14, wherein the information to be transferred comprises one or more letters, images, videos, music files, multimedia files, programs or combinations thereof.

18. A terminal device as claimed in claim 14, wherein the terminal device is mobile equipment, a PDA (Personal Digital Assistant) device, a portable computer or a media device.

19. A terminal device in a radio system, the terminal device comprising means for detecting that a charger connection is established between the terminal device and a charger, and means for detecting that the terminal device and a remote device are located at a distance from one another enabling a short-range wireless connection to be established therebetween, wherein the terminal device further comprises: connection means for establishing a short-range wireless connection between the terminal device and the remote device; and transferring means for transferring information between the terminal device and the remote device by using the established short-range wireless connection on the basis of the charger connection between the terminal device and the charger being established as well as detecting that the terminal device and the remote device are located at a distance from one another enabling a short-range wireless connection to be established therebetween.
